(19) United States
(12) Patent Application Publication
(10) Pub. No.: US 2012/0299113 A1
(43) Pub. Date: Nov. 29, 2012

(54) SEMICONDUCTOR DEVICE AND METHOD FOR FABRICATING THE SAME

(75) Inventors: Kenichi ENDO, Toyama (JP); Jun SUZUKI, Toyama (JP)

(73) Assignee: Panasonic Corporation, Kadoma-shi (JP)

(21) Appl. No.: 13/568,779

(22) Filed: Aug. 7, 2012

(30) Foreign Application Priority Data
Feb. 17, 2010 (JP) 2010-032762
Sep. 17, 2010 (JP) PCT/JP2010/005697

(51) Int. Cl. H01L 27/092

(52) U.S. Cl. 257/369; 257/E27.062

(57) ABSTRACT

In a first transistor of a semiconductor device, a first gate insulating film is located on a first active region, and the first gate insulating film includes a first high-κ material of a first metal oxide and a first metal which changes a flat-band voltage of the first transistor. In a second transistor of a semiconductor device, a second gate insulating film is located on a second active region, and the second gate insulating film includes a second high-κ material of a second metal oxide and a second metal which changes a flat-band voltage of the second transistor. The first metal oxide has an amorphous structure. The second metal oxide has a tetragonal or cubic crystal structure.

### CROSS-REFERENCE TO RELATED APPLICATION

This is a continuation of PCT International Application PCT/JP2010/005697 filed on Sep. 17, 2010, which claims priority to Japanese Patent Application No. 2010-032762 filed on Feb. 17, 2010. The disclosures of these applications including the specifications, the drawings, and the claims are hereby incorporated by reference in their entirety.

### BACKGROUND

The present disclosure relates to semiconductor devices and methods for fabricating the same, and more particularly to a semiconductor device including a high dielectric constant (hereinafter referred to as high-κ) gate insulating film and a method for fabricating the semiconductor device.

With increased speed and integration density of semiconductor devices, miniaturization of transistors has been advanced. A complementary metal oxide semiconductor (CMOS) transistor is constituted by two types of transistors: a negative channel metal oxide semiconductor (nMOS) transistor and a positive channel metal oxide semiconductor (pMOS) transistor. The nMOS transistor controls ON/OFF of current by movement of electrons. The pMOS transistor controls ON/OFF of current by movement of holes. The amount I_{d} (the linear region) of current (ON current) flowing in channel when a transistor is on is expressed by the following equation (1):

I_{d}=μWCₒₓ{(V_{gs}−Vₜ)V_{ds}−V_{ds}²/2}/L (1)

where μ is the mobility of carriers in an inversion layer to serve as channel, W is the gate width of the transistor, Cₒₓ is the capacitance of a gate oxide film, L is the gate length of the transistor, V_{gs} is the voltage between gate and source, Vₜ is the threshold voltage, and V_{ds} is the voltage between drain and source.

Equation (1) shows that it is sufficient to increase μ, W, Cₒₓ, or (V_{gs}−Vₜ) or to reduce L in order to further increase the speed of a semiconductor device, i.e., to obtain a larger amount of ON current. The speed of semiconductor devices has been increased by reducing the gate length L, i.e., by miniaturizing the dimensions of transistors. However, advancement of lithography techniques is now about to stop. Instead of a technique of increasing ON current of transistors by miniaturizing the dimensions of the transistors, a technique of increasing ON current of transistors by increasing μ or Cₒₓ has been developed. The capacitance Cₒₓ is expressed by the following equation (2):

Cₒₓ=∈₀∈_{γ}(S/Tₒₓ) (2)

where ∈₀ is a vacuum dielectric constant, and S is the area of a plane perpendicular to the thickness direction of a gate insulating film.

According to equation (2), to increase Cₒₓ, it is sufficient to increase the relative dielectric constant ∈_{γ} of a gate insulating film or to reduce the physical thickness Tₒₓ of the gate insulating film. Thus, to increase ON current, it has been attempted to minimize the physical thickness (the oxide thickness) Tₒₓ of the gate oxide film, for example.

Gate insulating films of CMOS transistors up to 45-nm generation are silicon dioxide films having a dielectric constant of 3.9, in general. However, thickness reduction of gate insulating films by miniaturizing the dimensions of transistors causes an increase in tunnel leakage current, and thereby, the transistors come to have high standby power consumption. The use of a material having a dielectric constant of 4.0 or more (i.e., a material having a high dielectric constant, hereinafter referred to as a high-κ material) for a gate insulating film can achieve reduction of the effective thickness (i.e., the equivalent oxide thickness: EOT) of the gate insulating film even if the actual thickness (i.e., the physical thickness) thereof is larger than that of a silicon dioxide film. For this reason, gate insulating films made of high-κ materials (hereinafter referred to as high-κ gate insulating films) have been developed.

However, when a conventional polysilicon gate electrode and a high-κ gate insulating film are used in combination, depletion occurs in a gate electrode, and it is difficult to obtain advantages of the high-κ gate insulating film, i.e., a small EOT. To prevent depletion in the gate electrode, the high-κ gate insulating film is preferably used together with a metal gate electrode. In forming a CMOS transistor using a high-κ gate insulating film and a metal gate electrode in combination, it is important how the threshold voltage is controlled.

In forming a CMOS transistor with polysilicon gate electrodes, the concentrations of impurities added to the polysilicon electrodes differ between an nMOS transistor and a pMOS transistor. This technique can control the Fermi level, thereby optimizing Vₜ of the nMOS transistor and the pMOS transistor. In addition, the configurations of the gate electrodes also differ between the nMOS transistor and the pMOS transistor.

A high-κ gate insulating film contains a large number of defects. Accordingly, when an impurity is implanted in channel, the impurity might be partially trapped in the high-κ gate insulating film. Thus, when impurity ions are implanted in an amount substantially equal to that of impurity ions implanted by, for example, general ion implantation, the impurity concentration in channel cannot be made different between the nMOS transistor and the pMOS transistor, and thus, Vₜ of the nMOS transistor and the pMOS transistor cannot be optimized (i.e., Fermi level pinning occurs) in some cases. To solve this problem, Vₜ of an nMOS transistor and a pMOS transistor in a CMOS transistor including high-κ gate insulating films is optimized not by a technique of making the impurity concentration in the channel region different between the nMOS transistor and the pMOS transistor but by a technique of making fixed charge and the difference in work function between a semiconductor and a metal different between the nMOS transistor and the pMOS transistor. The flat-band voltage Vfb is expressed by using a term (the first term of equation (3)) indicating the Fermi level due to ion implantation, a term (qNfix) indicated by fixed charge in the gate insulating film, and the difference (φms) between the work function of the metal gate electrode and the work function of the channel region, as shown by the following equation (3):

Vfb=(kT/q)ln(Na/ni)−qNfix−φms (3)

where k is a Boltzmann constant, T is an absolute temperature, q is a charge amount, Na is an impurity concentration in a Si substrate, ni is an intrinsic carrier concentration (up to 1.45×10¹⁰ (/cm³), and Nfix is the number of fixed charges.

Examples of a cap layer, a cap layer provided in an nMOS transistor) which shifts the flat-band voltage Vfb to a negative voltage include LaOₓ (where 0<x≦2.5). Examples of a cap layer (i.e., a cap layer provided in a pMOS transistor) which shifts the flat-band voltage Vfb to a positive voltage include AlO_{y} (where 0<y≦1.5).

An AlO_{y} film has a dielectric constant smaller than that of a high-κ film (e.g., a hafnium oxide film). Accordingly, the use of an AlO_{y} film as a cap layer causes an increase in EOT, and thereby, reduces advantages obtained by reducing the EOT by using a high-κ film in some cases.

To increase driving current or enhance the reliability of a high-κ gate insulating film to a degree substantially equal to or higher than that of a conventional SiON gate insulating film, a SiO₂ layer (with a thickness of about 1.0 nm) called an interlayer (an IL) is preferably provided between a semiconductor substrate and the high-κ gate insulating film. Specifically, it is required to reduce the EOT while using a cap film of an IL or AlO_{y} which reduces the dielectric constant of the gate insulating film and thereby increases the EOT. Accordingly, there is a need for a high-κ material with a high dielectric constant which can reduce an EOT increase even with an increase in physical thickness.

For example, U.S. Pat. No. 7,508,649 shows TiO and other materials as high-κ materials. However, if TiO is selected as a high-κ material, leakage current increases, resulting in an increase in power consumption of a semiconductor device.

Japanese Patent Publication No. 2008-306036 and “2008 Symposium on VLSI Technology Digest of Technical Papers pp. 152-153” describe that the dielectric constant of hafnium oxide (hereinafter referred to as “HfO_{z}” where 0<z≦2) can be increased when HfO_{z} has a cubic or tetragonal crystal structure. Specifically, a TiN film or a Poly-Si electrode is formed on a high-κ gate insulating film, and then annealing is performed at about 600-900° C. to crystallize HfO_{z}. Then, according to the above publications, the EOT can be further reduced.

### SUMMARY

However, it is difficult to fabricate a CMOS transistor with the technique of forming a TiN film or a Poly-Si electrode and then performing annealing thereon. In particular, when AlO_{y} is mixed in crystallized HfO_{z} (i.e., HfO_{z} crystallized to have a cubic or tetragonal crystal structure) of, for example, a pMOS transistor in order to optimize the flat-band voltage Vfb, the amount of change in the flat-band voltage is smaller than that in a case where AlO_{y} is mixed in amorphous HfO_{z}. The same holds for an nMOS transistor.

In addition, if annealing is performed after formation of a TiN film on a high-κ gate insulating film, this annealing causes Ti to be easily diffused in the high-κ gate insulating film, resulting in that TiO is formed in the high-κ gate insulating film. This phenomenon is a cause of an increase in leakage current.

It is therefore an object of the present disclosure to further increase the dielectric constant of a gate insulating film while reducing an increase in leakage current.

To achieve the object, the inventors of the present disclosure intensively investigated conditions for crystallization of a high-κ material, to obtain the following findings.

A film which readily shrinks by heat treatment (hereinafter referred to as a “stressed film”) is formed on a high-κ film, and is subjected to annealing at 600° C. or more. Then, the stressed film shrinks, and thereby, the high-κ material is crystallized to have a cubic or tetragonal crystal structure.

A first example method for fabricating a semiconductor device according to the present disclosure includes the steps of: (a) forming a high-κ film of a metal oxide on a semiconductor substrate; (b) forming a stressed film on the high-κ film; and (c) performing heat treatment at 600° C. or more after step (b). Through steps (a)-(c), the high-κ film forms a gate insulating film with a tetragonal or cubic crystal structure.

In a preferred embodiment as described below, the heat treatment performed in step (c) causes the stressed film to have a tensile stress or changes an internal stress of the stressed film from a compressive stress to a tensile stress. In this case, the stressed film is preferably at least one of SiN, SiO₂, TiOₓ, TaOₓ, YOₓ, SiBN, SiCN, or SiBCN (where 0<x≦2.5), and is preferably formed by plasma CVD.

In a preferred embodiment as described below, the heat treatment performed in step (c) causes the stressed film to have a tensile stress or changes an internal stress of the stressed film from a compressive stress to a tensile stress. In this case, the stressed film is preferably at least one of TiN, TaN, TaCN, TaC, AlN, HfN, W, or WN, and the stressed film is preferably formed by PVD.

A second example method for fabricating a semiconductor device according to the present disclosure is a method for fabricating a semiconductor device including a first transistor of a first conductivity type located on a first active region in a semiconductor region and a second transistor of a second conductivity type located on a second active region in the semiconductor region, the second active region being separated from the first active region by an isolation region. Specifically, the second example method includes the steps of: (d) forming a high-κ film of a metal oxide on the first active region and the second active region; (e) forming, on the first active region, a first cap film containing a first metal which changes a flat-band voltage of the first transistor; (f) forming, on the second active region, a second cap film containing a second metal which changes a flat-band voltage of the second transistor; (g) forming a stressed film having a tensile stress on the high-κ film on the second active region; and (h) performing heat treatment at 600° C. or more after steps (e)-(g). This method makes it possible to further increase the dielectric constant of a gate insulating film while reducing an increase in leakage current.

In the second example method, step (h) preferably includes the steps of: diffusing the first metal from the first cap film to a portion of the high-κ film located on the first active region; and crystallizing the metal oxide into a tetragonal or cubic crystal structure on the second active region.

A semiconductor device fabricated with the second example method has the following configuration. In a first transistor, a first gate insulating film is located on a first active region, and the first gate insulating film includes a first high-κ material of a first metal oxide and a first metal which changes a flat-band voltage of the first transistor. In a second transistor, a second gate insulating film is located on a second active region, and the second gate insulating film includes a second high-κ material of a second metal oxide and a second metal which changes a flat-band voltage of the second transistor. The first metal oxide has an amorphous structure. The second metal oxide has a tetragonal or cubic crystal structure.

In a preferred embodiment as described below, the first transistor is an nMOS transistor, the second transistor is a pMOS transistor, each of the first metal oxide and the second metal oxide includes at least one of hafnium, zirconium, or titanium, the first metal is lanthanum, and the second metal is aluminium.

According to the present disclosure, it is possible to further increase the dielectric constant of a gate insulating film while reducing an increase in leakage current.

### BRIEF DESCRIPTION OF THE DRAWINGS

FIGS. 1A-1C are cross-sectional views showing a method for fabricating a semiconductor device in the order of fabrication processes according to an embodiment of the present disclosure.

FIGS. 2A-2C are cross-sectional views showing the method for fabricating a semiconductor device in the order of fabrication processes according to the embodiment.

FIG. 3A is a graph showing a relationship between an EOT and an eWF (a work function) in a case where Ti is diffused in a HfO_{z} film and a case where Ti is not diffused in a HfO_{z} film. FIG. 3B is a graph showing a relationship between an EOT and a leakage current (Jg) in a case where Ti is diffused in a HfO_{z} film and a case where Ti is not diffused in a HfO_{z} film.

FIG. 4A is a graph showing results of X-ray diffraction (XRD) performed on samples obtained by forming a TiN film on a HfO_{z} film and then performing heat treatment thereon. FIG. 4B is a cross-sectional TEM photograph of a HfO_{z} film in a case where a TiN film is formed by physical vapor deposition (PVD). FIG. 4C is a cross-sectional TEM photograph of a HfO_{z} film in a case where a TiN film is formed by atomic layer deposition (ALD).

FIG. 5A is a graph showing results of XRD performed on samples obtained by forming an insulating film on a HfO_{z} film and then performing heat treatment thereon. FIG. 5B is a cross-sectional TEM photograph of a HfO_{z} film in a case where a SiN film is formed on a HfO_{z} film by plasma chemical vapor deposition (CVD).

FIGS. 6A-6D are views schematically illustrating changes in bending of a substrate before and after heat treatment.

FIG. 7 is a graph showing a relationship between the optical thickness and the EOT of an HfO_{z} film.

FIG. 8 is a graph showing a relationship between an EOT and a leakage current Jg.

FIG. 9 is a graph showing a relationship between a gate voltage Vg and a capacity.

### DETAILED DESCRIPTION

An embodiment of the present disclosure will be hereinafter described with reference to the drawings. The present disclosure is not limited to the following embodiment.

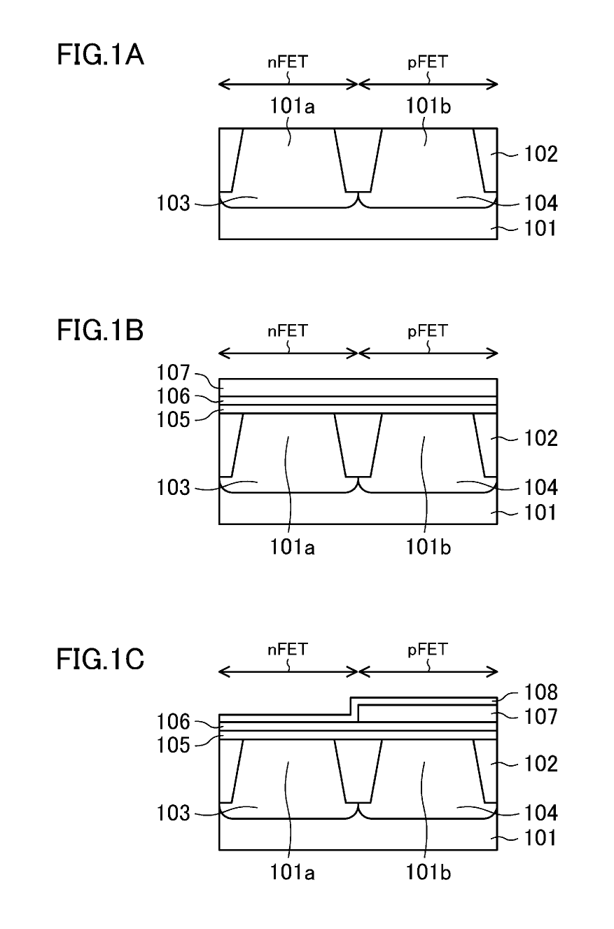

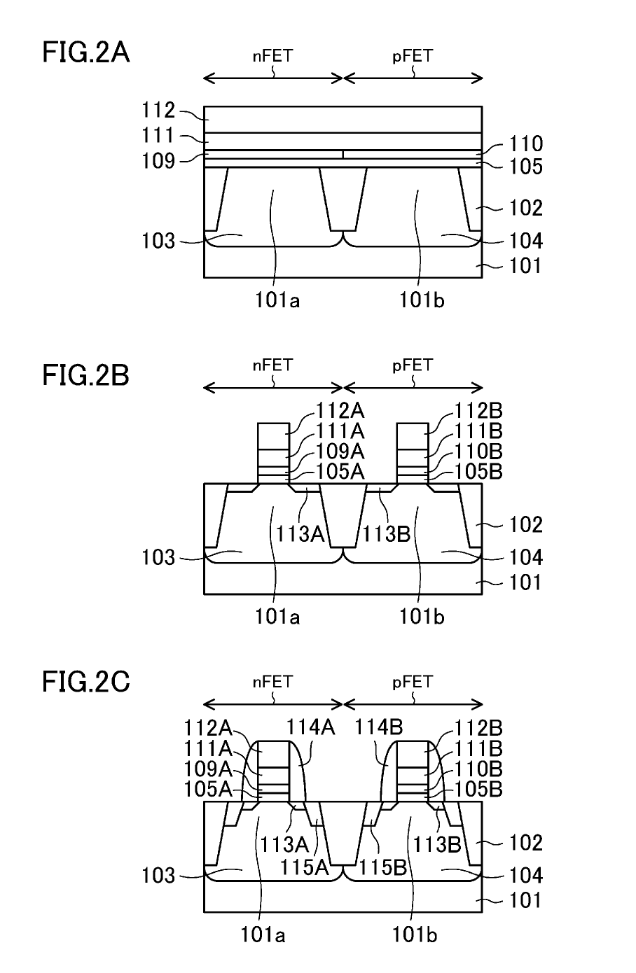

FIGS. 1A-2C are cross-sectional views showing a method for fabricating a semiconductor device in the order of fabrication processes according to this embodiment. In the drawings, “nFET” refers to an nMOS transistor region where an nMOS transistor is to be formed, and “pFET” refers to a pMOS transistor region where a pMOS transistor is to be formed.

First, as illustrated in FIG. 1A, a trench (not shown) is formed in a substrate 101 of, for example, silicon (hereinafter referred to as a “substrate”), and is filled with SiO₂. Accordingly, an isolation region 102 is formed in the substrate 101. In an nMOS transistor region nFET, a first active region 101a surrounded by the isolation region 102 is defined in the substrate 101. In a pMOS transistor region pFET, a second active region 101b surrounded by the isolation region 102 is defined in the substrate 101. Thereafter, a p-well region 103 is formed in the first active region 101a, and an n-well region 104 is formed in the second active region 101b.

Next, the upper surface of the substrate 101 is oxidized in a steam atmosphere or a nitrogen monoxide atmosphere. Accordingly, a SiO₂ layer (not shown, with a thickness of, for example, 0.5-1.2 nm), for example, is formed in the upper surface of the substrate 101. This SiO₂ layer is called an interface layer or an inter layer (IL).

Subsequently, a high-κ film with a thickness of, for example, 0.5-2.0 nm is formed on the SiO₂ layer (step (a) and step (d)). For example, HfO_{z} (hafnium aluminate) containing Al (a second metal) may be formed over the entire upper surface of the SiO₂ layer by ALD or PVD. In this process, Al may be segregated in a portion of the high-κ film near the IL or may be present as a cap layer on the HfO_{z} film. In this embodiment, as illustrated in FIG. 1B, an AlO_{y} film 105 is formed on the SiO₂ film (the IL) (step (f)), and then a HfO_{z} film 106 is formed on the AlO_{y} film (the second cap film) 105. Accordingly, Al is segregated in a portion near the IL. The thickness ratio of the AlO_{y} film 105 to the HfO_{z} film 106 only needs to be 40% or less, and is preferably in the range from 10% to 40%, both inclusive.

To optimize the threshold voltage (Vₜ) of the pMOS transistor, i.e., to enhance the effective work function (eWF) of the pMOS transistor, AlO_{y} is added to the pMOS transistor. However, the dielectric constant of AlO_{y} is smaller than that of a high-κ material such as HfO_{z}. Accordingly, addition of AlO_{y} causes an increase in EOT. To reduce an increase in EOT, it is effective to increase the dielectric constant of the entire gate insulating film by crystallizing the high-κ material into a cubic or tetragonal crystal structure. As a method for crystallizing a high-κ material into a cubic or tetragonal crystal structure, a technique of covering a high-κ film with a TiN film and performing heat treatment on the high-κ film at 800° C. or more (as disclosed in “2008 Symposium on VLSI Technology Digest of Technical Papers pp. 152-153”) is known. This technique, however, causes Ti to be diffused in the high-κ film during the heat treatment, and a portion where Ti is diffused (i.e., Ti present in the high-κ film) serves as a leakage spot, resulting in an increase in leakage current.

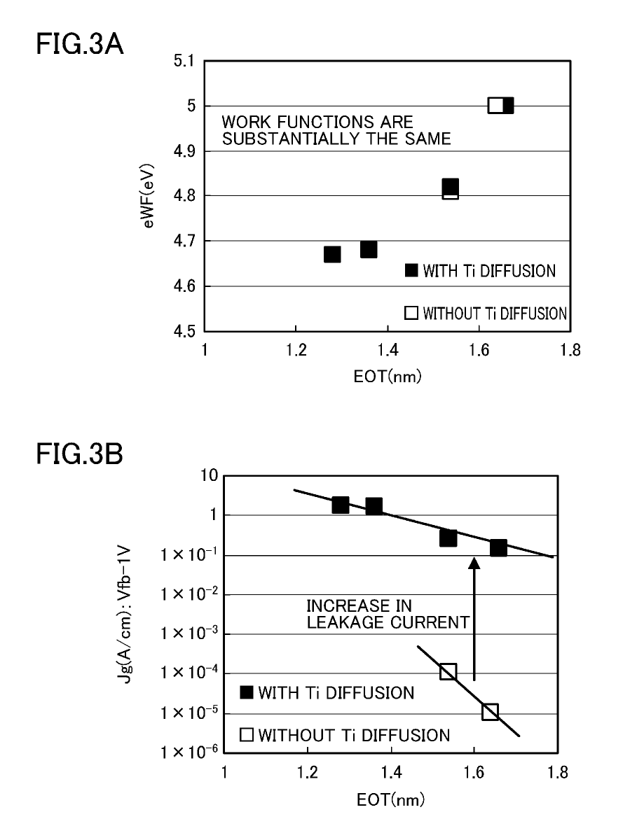

FIG. 3A is a graph showing a relationship between the EOT and the eWF (the work function) of the pMOS transistor in a case where Ti is diffused in the HfO_{z} film and a case where Ti is not diffused in the HfO_{z} film. FIG. 3B is a graph showing a relationship between the EOT and a leakage current (Jg) occurring in the pMOS transistor in a case where Ti is diffused in the HfO_{z} film and a case where Ti is not diffused in the HfO_{z} film.

The relationship between the EOT and the eWF (the work function) of the pMOS transistor hardly differs between the case where Ti is diffused in the HfO_{z} film and the case where Ti is not diffused in the HfO_{z} film. On the other hand, as long as the EOTs are the same, the leakage current (Jg) occurring in the pMOS transistor in the case where Ti is diffused in the HfO_{z} film is larger than that in the case where Ti is not diffused in the HfO_{z} film by two to three digits or more. This is considered to be because diffusion of Ti in the HfO_{z} film forms a path for leakage current.

From the results shown in FIGS. 3A and 3B, the following conclusion is drawn. That is, the technique of covering the high-κ film with the TiN film and performing heat treatment thereon to crystallize HfO_{z} into a cubic crystal structure is likely to cause an increase in leakage current, and thus, it is difficult to form a low power consumption device by using this technique. As a technique for forming a TiN film, techniques such as PVD, CVD, and ALD are known. However, “2008 Symposium on VLSI Technology Digest of Technical Papers pp. 152-153” does not mention how a TiN film is formed. In addition, “2008 Symposium on VLSI Technology Digest of Technical Papers pp. 152-153” does not explain a mechanism by which HfO_{z} is crystallized into a cubic crystal structure by covering the high-κ film with the TiN film and then performing heat treatment thereon. Thus, inventors of the present disclosure intensively investigated the mechanism.

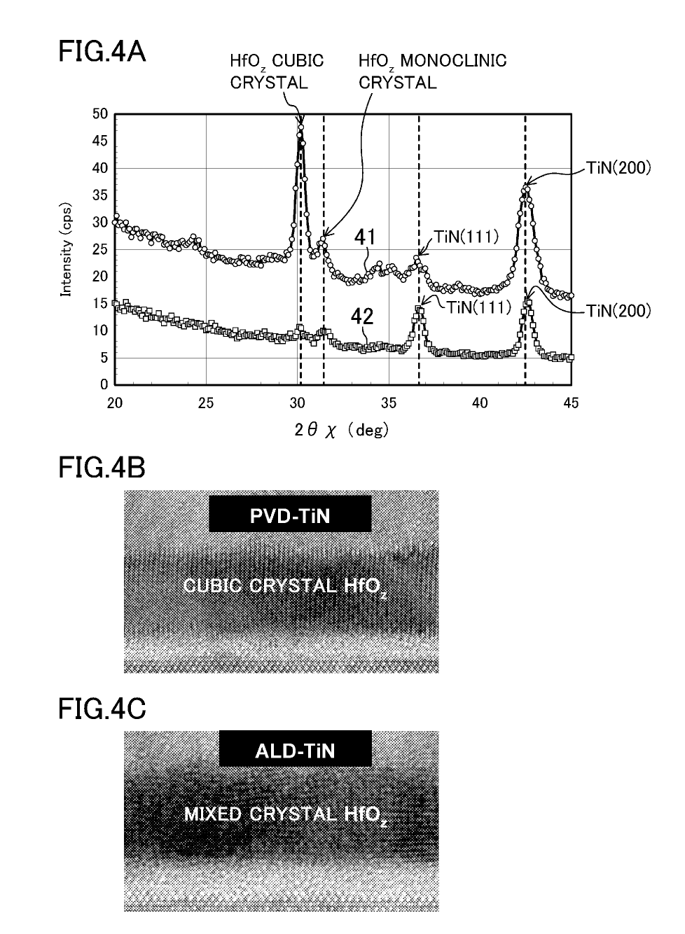

FIG. 4A is a graph showing results of XRD performed on samples obtained by forming a TiN film on the HfO_{z} film and then performing heat treatment thereon. A line 41 in FIG. 4A indicates a result in a case where the TiN film is formed by PVD. A line 42 in FIG. 4A indicates a result in a case where the TiN film is formed by ALD. In the case where the TiN film is formed by ALD (indicated by the line 42), a peak of 2θ=30.2 degrees, which belongs to a peak of the cubic crystal structure of HfO_{z}, did not appear. On the other hand, in the case where the TiN film is formed by PVD (indicated by the line 41), a peak of the cubic crystal structure of HfO_{z} appeared.

In the XRD analysis shown in FIG. 4A, the X-ray spot diameter needs to be 100×100 μm² at minimum in order to increase the diffraction intensity, and the area subjected to this analysis was 400×200 μm². Thus, it is difficult to perform XRD analysis on the gate electrode of a transistor having a gate length of 50 nm or less. However, if the gate electrode of the transistor is observed with a cross-sectional transmission electron microscopy (TEM), crystal orientation of HfO_{z} can be easily observed, thus enabling the crystal structure of HfO_{z} to be estimated. FIG. 4B is a cross-sectional TEM photograph of a HfO_{z} film in the case where the TiN film is formed by PVD. FIG. 4C is a cross-sectional TEM photograph of a HfO_{z} film in the case where the TiN film is formed by ALD. In the case where the TiN film is formed by PVD, Hf atoms are arranged vertically (i.e., in the up-and-down direction in FIG. 4B). That is, HfO_{z} has a cubic crystal structure. The crystal orientation rate can be quantified by determining the crystal orientation rate by electron beam diffraction. On the other hand, in the case where the TiN film is formed by ALD, Hf atoms are not arranged in one direction, i.e., HfO_{z} does not have a cubic crystal structure but has a mixed crystal structure in which an amorphous region and a crystal region are microscopically mixed together.

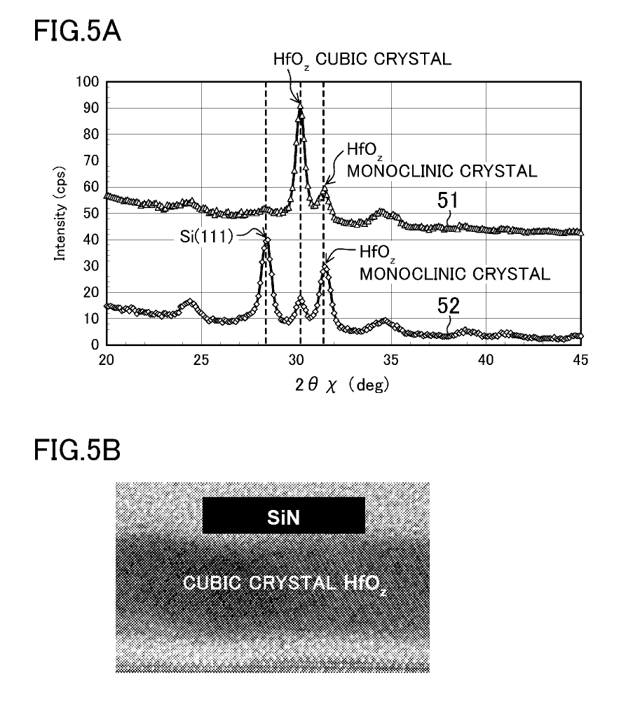

FIG. 5A is a graph showing results of XRD performed on samples obtained by forming an insulating film on a HfO_{z} film and then performing heat treatment thereon. A line 51 in FIG. 5A indicates a result in a case where a SiN film is formed on the HfO_{z} film by plasma CVD. A line 52 in FIG. 5A indicates a result in a case where an amorphous Si film is formed on the HfO_{z} film. FIG. 5B is a cross-sectional TEM photograph of the HfO_{z} film in a case where a SiN film is formed on the HfO_{z} film by plasma CVD. In the case where an amorphous Si film is formed on the HfO_{z} film (indicated by the line 52), a peak of 2θ=30.2 degrees, which belongs to a peak of the cubic crystal structure of HfO_{z}, did not appear. On the other hand, in the case where a SiN film is formed by plasma CVD (indicated by the line 51), a peak of the cubic crystal structure of HfO_{z} appeared. This is also clearly shown in the cross-sectional TEM photograph of FIG. 5B.

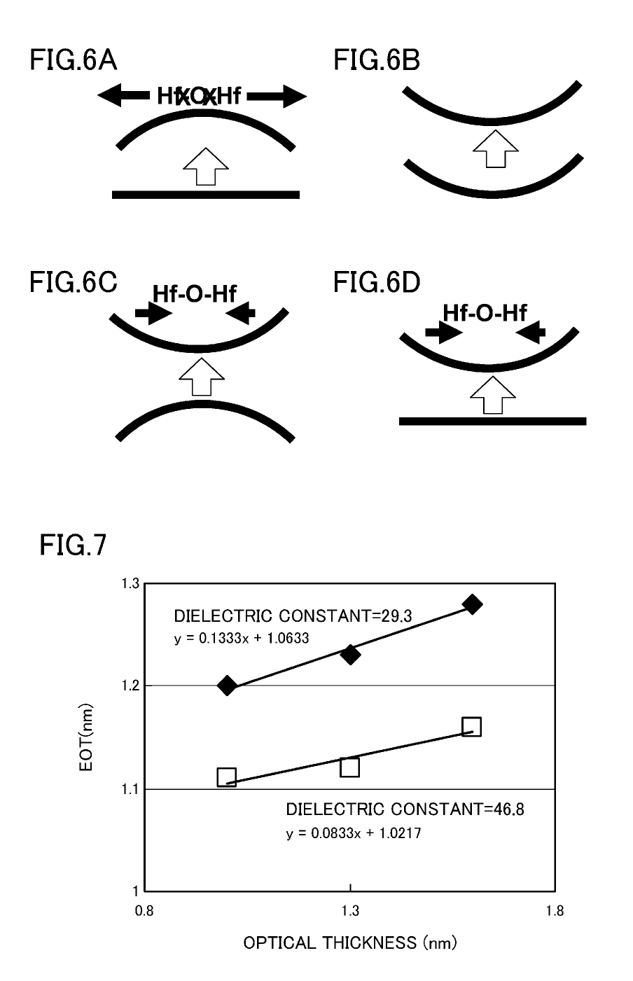

From the foregoing results, inventors of the present disclosure concluded that the crystal structure of the high-κ material after heat treatment differs between the methods for forming a film on the high-κ film as described above because of the influence of bending of a substrate before and after the heat treatment (i.e., heat treatment performed at 600° C. or more). FIGS. 6A-6D are views schematically illustrating variations of bending of a substrate before and after the heat treatment. Each of FIGS. 6A-6D schematically shows the degree of bending of the substrate before the heat treatment below the white arrow, and the degree of bending of the substrate after the heat treatment above the white arrow. FIGS. 6A-6D show a case where an amorphous Si film is formed on the high-κ film, the case where a TiN film is formed on the high-κ film by ALD, a case where a TiN film is formed on the high-κ film by PVD, and a case where a SiN film is formed on the high-κ film by plasma CVD, respectively.

In the case where an amorphous Si film is formed on the HfO_{z} film (FIG. 6A), the substrate bends upward (i.e., toward the amorphous Si film). Accordingly, a stress (a tensile stress) which breaks Hf—O bonding is applied to the HfO_{z} film. Consequently, HfO_{z} is not easily crystallized into a cubic crystal structure (which is the densest crystal structure). In the case where a TiN film is formed on the HfO_{z} film by ALD (FIG. 6B), the degree of bending of the substrate does not change after the heat treatment. Accordingly, a large stress is not applied to the HfO_{z} film, resulting in difficulty in changing the crystal structure of HfO_{z}.

On the other hand, in the case where a TiN film is formed on the HfO_{z} film by PVD (FIG. 6C), the substrate bends upward before the heat treatment, and bends downward after the heat treatment. In this manner, the internal stress of the TiN film formed by PVD changes from a compressive stress to a tensile stress by the heat treatment. In the case where a SiN film is formed on the HfO_{z} film by plasma CVD (FIG. 6D), the substrate does not bend in any direction (i.e., upward or downward) before the heat treatment, and bends downward after the heat treatment. In this manner, the SiN film formed by plasma CVD comes to have a tensile stress by the heat treatment. Specifically, formation, on the HfO_{z} film, of a film which can change bending of the substrate toward a tensile stress by heat treatment can crystallize HfO_{z} into a cubic crystal structure. This is because of the following reasons.

In general, when a metal oxide is crystallized into a cubic crystal structure, the cubic crystal structure is defined by closest packing called random close packing of oxygen atoms, and then atoms of a metal such as Hf are arranged in the defined structure. Accordingly, if a film formed on a HfO_{z} film has a tensile stress, a substrate can be caused to bend downward by heat treatment, thereby compressing HfO_{z}. In this manner, HfO_{z} can have a cubic crystal structure, which is the closest crystal structure. This holds true not only for the case of controlling the crystal structure of HfO_{z} but also the cases of controlling the crystal structures of, for example, ZrO_{z} (0<z≦2), LaOₓ, and TaOₓ.

Examples of the film caused to have a tensile stress by heat treatment as described above include a SiO₂ film, a TiOₓ film, a TaOₓ film, a YOₓ film, a SiBN film, a SiCN film, and a SiBCN film (in each of these films, 0<x≦2.5) formed by plasma CVD, and also include a TiN film, TaN film, a TaCN film, a TaC film, an AlN film, a HfN film, a W film, and a WN film formed by PVD. Among these films, the use of the SiN film formed by plasma CVD as a stressed film can obtain the following two advantages. First, since HfO_{z} and SiN have high selectivities in dry etching using fluorine plasma and high selectivities in cleaning with phosphoric acid, the SiN film can be easily removed in the process shown in FIG. 2A. Second, since diffusion of SiN into the high-κ film can be reduced, an increase in leakage current can be reduced. For these reasons, this embodiment employs the SiN film formed by plasma CVD as a stressed film.

The high-κ film of the nMOS transistor preferably includes a metal (a first metal such as La) which can reduce the flat-band voltage. However, the atomic radius of La is larger than that of Hf, and thus, it is difficult to diffuse La into a HfO_{z} film crystallized to have a cubic crystal structure. In view of this, in the method for fabricating a semiconductor device of this embodiment, La is diffused into the high-κ film of the nMOS transistor concurrently with crystallization of HfO_{z} into the cubic crystal structure. The method for fabricating a semiconductor device of this embodiment will be further described below.

A SiN film (a stressed film) 107 is formed on the HfO_{z} film 106 by plasma CVD (step (b) and step (g)). The plasma CVD is performed under conditions that the deposition temperature is 300° C., the flow rate of SiH₄ is 60 sccm, the flow rate of NH₃ is 900 sccm, and the radio frequency (RF) is 100 W. The thickness of the SiN film 107 only needs to be in the range from 10 nm to 30 nm, both inclusive.

Then, the pMOS transistor region pFET is patterned using a resist film (not shown), and then part of the SiN film 107 located in the nMOS transistor region nFET is dry-etched. Specifically, part of the SiN film 107 located in the nMOS transistor region nFET is irradiated with fluorine radicals, thereby volatilizing SiN as SiF. The boiling point of SiF₄ is −94.8° C., the sublimation point of HfF₄ is 970° C., and the dry-etching selection ratio between SiN and HfO_{z} can be set at a preferred value by using a fluorocarbon-based gas. As dry etching conditions, the pressure is 25 mT, the RF is 575 W, and Ar:CF₄:CHF₃:CH₂F₂:O₂=1500:50:80:10:20 sccm (flow rate ratio), for example. After the dry etching, the resist film is removed.

Subsequently, as shown in FIG. 1C, a LaOₓ film (a first cap film) 108 is formed by ALD or PVD (step (e)). Accordingly, the LaOₓ film 108 covers the HfO_{z} film 106 in the nMOS transistor region nFET and the SiN film 107 in the pMOS transistor region pFET. The LaOₓ film 108 has a thickness of, for example, 1-3 nm. Thereafter, heat treatment is performed at 700-900° C. for 1-10 minutes, for example (step (c) and step (h)). The heat treatment is performed with a resistance heater or a lamp heater. The temperature and the time of the heat treatment can be set according to a target flat-band voltage Vfb of the nMOS transistor.

This heat treatment causes La to be diffused from the LaOₓ film 108 to the HfO_{z} film 106 in the nMOS transistor region nFET, thereby forming a HfO_{z} film 109 containing La on the AlO_{y} film 105 (see FIG. 2A). Accordingly, the flat-band voltage Vfb of the nMOS transistor has a desired value.

On the other hand, in the pMOS transistor region pFET, a compressive stress is applied to the HfO_{z} film, thereby forming a HfO_{z} film 110 crystallized into a cubic crystal structure on the AlO_{y} film 105 (see FIG. 2A). Accordingly, the flat-band voltage Vfb of the pMOS transistor has a desired value.

After the heat treatment, the remaining part of the LaOₓ film which is not diffused in the HfO_{z} film 106 and part of the LaOₓ film formed on the SiN film 107 are removed using an etchant of HCl:H₂O=1:1000 (volume ratio). Part of the SiN film 107 located in the pMOS transistor region pFET is removed using hot phosphoric acid at 120-160° C.

Thereafter, a TiN film 111 is formed by ALD or PVD on the HfO_{z} film 109 containing La and the crystallized HfO_{z} film 110. As a material for forming the TiN film 111, a TiCl₄ and ammonia, for example, may be used in combination. As a Ti source, not TiCl₄ but amino- or imido-titanium, for example, may be used. As a N source, not ammonia but ammonia radicals produced by applying plasma to ammonia or ionized nitrogen, for example, may be used.

Then, a polysilicon film 112 is formed on the TiN film 111. Specifically, SiH₄ may be caused to flow at 600-630° C., for example. Instead of the polysilicon film 112, a silicon germanium film may be formed by adding silane and germane (GeH₄).

Subsequently, a gate electrode resist pattern (not shown) is formed by photolithography and etching, and anisotropic etching is performed, using a halogen-based etching gas, on the polysilicon film 112, the TiN film 111, the HfO_{z} film 110 crystallized into a cubic crystal structure, the HfO_{z} film 109 containing La, and the AlO_{y} film 105. In this manner, as shown in FIG. 2B, a first gate insulating film of a La-containing HfO_{z} film 109A and a first gate electrode of a first metal electrode 111A and a first polysilicon electrode 112A are stacked in this order on the first active region 101a. On the second active region 101b, a second gate insulating film of an AlO_{y} film 105B and a HfO_{z} film 110B crystallized into a cubic crystal structure and a second gate electrode of a second metal electrode 111B and a second polysilicon electrode 112B are stacked in this order.

Thereafter, the remaining part of the high-κ film which is not dry-etched is removed by cleaning using a hydrogen fluoride-based material. Subsequently, a silicon nitride film (not shown) is formed over the entire upper surface of the substrate 101 at 600° C. or less. The technique for forming the silicon nitride film is most preferably ALD. For example, the silicon nitride film is preferably deposited to a thickness of 5-10 nm by alternately supplying dichlorosilane (SiH₂Cl₂) and ammonia. Then, the silicon nitride film is dry-etched using a halogen-based gas, thereby forming a silicon nitride film (not shown) on side surfaces of the first gate electrode and the second gate electrode.

Subsequently, ions of an n-type impurity such as phosphorus, arsenic, or antimony are implanted into the p-well region 103 with the n-well region 104 covered with a resist. Thereafter, the resist is removed from the n-well region 104, and then the p-well region 103 is covered with a resist. Then, ions of a p-type impurity such as boron or indium are implanted into the n-well region 104, and heat treatment is performed thereon at 900-1000° C., thereby activating the implanted ions. Accordingly, as shown in FIG. 2B, n-type extension regions 113A are formed below the first gate electrode in the first active region 101a and located at the sides of the first gate electrode when viewed from above the first electrode, whereas p-type extension regions 113B are formed below the second gate electrode in the second active region 101b and located at the sides of the second gate electrode when viewed from above the second electrode.

Then, a silicon oxide film with a thickness of 5-10 nm and a silicon nitride film with a thickness of 10-30 nm are formed in this order over the entire upper surface of the substrate 101, and anisotropic dry etching is performed on the silicon oxide film and the silicon nitride film. Accordingly, first sidewalls 114A are formed on side surfaces of the first gate electrode, and second sidewalls 114B are formed on side surfaces of the second gate electrode. Each of the sidewalls may be made of a single layer of a silicon oxide film or a single layer of a silicon nitride film.

Subsequently, ions of an n-type impurity such as phosphorus, arsenic, or antimony are implanted into the p-well region 103 with an upper portion of the n-well region 104 covered with a resist (not shown). Thereafter, the resist is removed from the n-well region 104, and then an upper portion of the p-well region 103 is covered with a resist (not shown). Then, ions of a p-type impurity such as boron or indium are implanted into the p-well region 103. Thereafter, heat treatment is performed thereon at 900-1050° C., thereby activating the implanted ions. Accordingly, as shown in FIG. 2C, n-type source/drain regions 115A are formed below the first sidewalls 114A in the first active region 101a and located at the sides of the first sidewalls 114A when viewed from above the first sidewalls 114A, whereas p-type source/drain regions 115B are formed below the second sidewalls 114B in the second active region 101b and located at the sides of the second sidewalls 114B when viewed from above the second sidewalls 114B. In the manner described above, a semiconductor device shown in FIG. 2C can be obtained.

Then, upper portions of the n-type source/drain regions 115A, the p-type source/drain regions 115B, the first polysilicon electrode 112A, and the second polysilicon electrode 112B are silicided with Ni or Pt. Thereafter, a silicon nitride film (not shown, and serving as an etching stopper in forming a contact hole) and a silicon oxide film (not shown, and serving as an interlayer insulating film) are formed over the entire upper surface of the substrate 101, and ordinary processes including planarization are performed.

Characteristics of the semiconductor device of this embodiment will now be described.

FIG. 7 is a graph showing a relationship between the optical thickness and the EOT of the HfO_{z} film. White squares (□) in FIG. 7 indicate a result in a case where HfO_{z} is crystallized into a cubic crystal structure with the method of this embodiment, and black squares (▪) in FIG. 7 indicate a result in a case where HfO_{z} is not crystallized into a cubic crystal structure.

In the case where HfO_{z} is not crystallized into a cubic crystal structure, the HfO_{z} gate insulating film containing AlO_{y} has a dielectric constant of 29.3. On the other hand, in the case where HfO_{z} is crystallized into a cubic crystal structure, the dielectric constant of the HfO_{z} film converted into the dielectric constant of HfO_{z} containing AlO_{y} is 46.8.

The dielectric constant is a value obtained by dividing 3.9, which is the dielectric constant of SiO₂, by the slope of the linear function of the EOT with respect to the optical thickness. The dielectric constant shown in “2008 Symposium on VLSI Technology Digest of Technical Papers pp. 152-153” is the dielectric constant of only HfO_{z}. On the other hand, in this embodiment, the dielectric constant of HfO_{z} containing AlO_{y} can be increased.

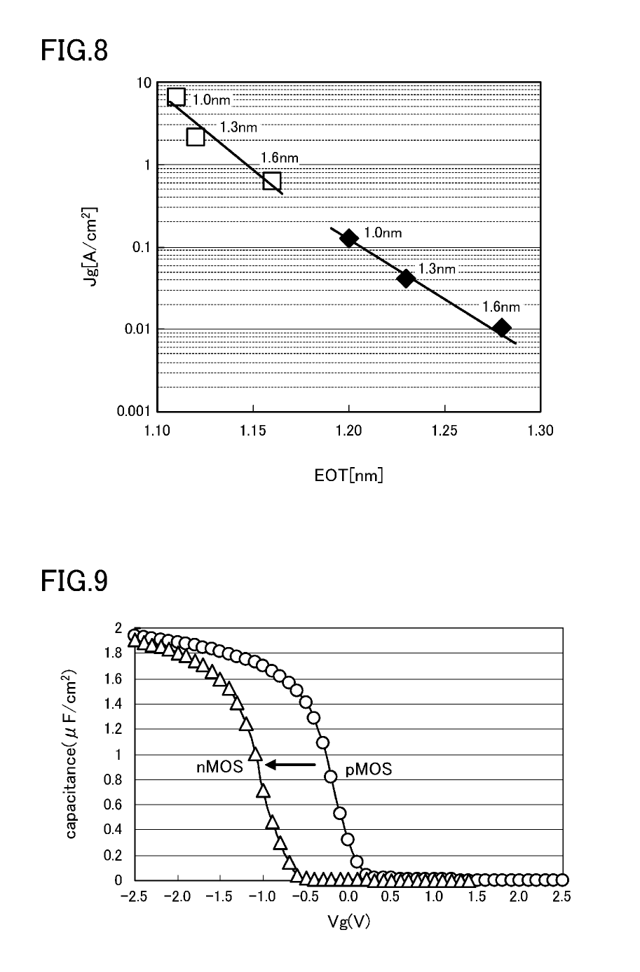

FIG. 8 is a graph showing a relationship between an EOT and a gate leakage current Jg. White squares (□) in FIG. 8 indicate a result in a case where HfO_{z} is crystallized into a cubic crystal structure with the method of this embodiment, and black squares (▪) in FIG. 8 indicate a result in a case where HfO_{z} is not crystallized into a cubic crystal structure. The gate leakage current value is a leakage current value with a voltage obtained by subtracting 1.0 V from Vfb. The gate leakage current value has a correlation with the EOT. The leakage current value in the case where HfO_{z} is crystallized into a cubic crystal structure is larger than that in the case where HfO_{z} is not crystallized into a cubic crystal structure. However, the result in the case where HfO_{z} is crystallized into a cubic crystal structure and the result in the case where HfO_{z} is not crystallized into a cubic crystal structure are substantially on the same line. Accordingly, an increase in leakage current in the case where HfO_{z} is crystallized into a cubic crystal structure is not due to an increase in leakage current depending on film properties as shown in FIG. 3B. In addition, in the case where HfO_{z} is not crystallized into a cubic crystal structure, the EOT was increased only to 1.2 nm even by setting the thickness of the HfO_{z} film at 1.0 nm. On the other hand, in the case where HfO_{z} is crystallized into a cubic crystal structure, the EOT can be made larger than the upper limit of the EOT in the case where HfO_{z} is not crystallized into a cubic crystal structure.

FIG. 9 is a graph showing a relationship between a gate voltage Vg and a capacity. In this embodiment, La is diffused in amorphous HfO_{z}, and thus, the flat-band voltage Vfb of the nMOS transistor was lower than that at the mid gap. Specifically, the nMOS transistor had a work function of 4.20 eV, and the pMOS transistor had a work function of 4.95 eV. Accordingly, the flat-band voltages of the nMOS transistor and the pMOS transistor can have desired values.

As described above, inventors of the present disclosure intensively investigated a method for crystallizing a HfO_{z} film into a cubic crystal structure, to find that if a film formed on a high-κ film has a tensile stress as a result of heat treatment at 600° C. or more, this high-κ material can be crystallized into a cubic crystal structure. The film having a tensile stress as a result of heat treatment at 600° C. or more may be a SiO₂ film, a TiOₓ film, a TaOₓ film, a YOₓ film, a SiBN film, a SiCN film, or a SiBCN film formed by plasma CVD, or a TiN film, a TaN film, a TaCN film, a TaC film, an AlN film, a HfN film, a W film, or a WN film formed by PVD. This is newly found by the inventors of the present disclosure.

This embodiment may employ the following configurations.

In the process shown in FIG. 1B, after the AlO_{y} film has been formed over the entire upper surface of the substrate, the AlO_{y} film may be removed from the nMOS transistor region nFET.

As a result of the heat treatment performed in the process shown in FIG. 1C, even when HfO_{z} has a tetragonal crystal structure, the same advantages as those obtained in this embodiment can be obtained.

In the process shown in FIG. 1C, after the LaOₓ film has been formed on the entire upper surface of the substrate 101, the LaOₓ film may be removed from the pMOS transistor region pFET and then subjected to heat treatment.

In the process shown in FIG. 1C, heat treatment may be performed together with application of ultraviolet radiation.

The temperature of the heat treatment in the process shown in FIG. 1C is not limited to the range from 700° C. to 900° C., both inclusive, and only needs to be in the range from 600° C. to 950° C., both inclusive.

A material constituting the high-κ film may be an oxide of, for example, hafnium (Hf), zirconium (Zr), or yttrium (Y). In any case, the same advantages as those obtained in this embodiment can be obtained.

The first metal is a metal which shifts the gate voltage Vg to a negative value when being added to the high-κ film, and may be a lanthanoid-based element, scandium (Sc), strontium (Sr), or magnesium (Mg), for example.

The second metal is a metal which shifts the gate voltage Vg to a positive value, and may be tantalum, instead of aluminium.

A semiconductor device and a method for fabricating a semiconductor device according to the present disclosure are preferably used for various types of electronic equipment using semiconductor integrated circuits.

What is claimed is:

1. A semiconductor device, comprising:
a first transistor of a first conductivity type located on a first active region in a substrate; and
a second transistor of a second conductivity type located on a second active region in the substrate, the second active region being separated from the first active region by an isolation region, wherein
in the first transistor,
a first gate insulating film is located on the first active region, and
the first gate insulating film includes a first high-κ material of a first metal oxide and a first metal which changes a flat-band voltage of the first transistor,
in the second transistor,
a second gate insulating film is located on the second active region, and
the second gate insulating film includes a second high-κ material of a second metal oxide and a second metal which changes a flat-band voltage of the second transistor,
the first metal oxide has an amorphous structure, and
the second metal oxide has a tetragonal or cubic crystal structure.

2. The semiconductor device of claim 1, wherein
the first transistor is an nMOS transistor,
the second transistor is a pMOS transistor,
each of the first metal oxide and the second metal oxide includes at least one of hafnium, zirconium, or yttrium,
the first metal is lanthanoid, scandium, strontium, or magnesium, and
the second metal is aluminium or tantalum.

3. The semiconductor device of claim 2, wherein
each of the first metal oxide and the second metal oxide is hafnium oxide,
the first metal is lanthanum, and
the second metal is aluminium.

4. The semiconductor device of claim 1, wherein
an interface layer is provided at an interface between the first active region and the first gate insulating film and an interface between the second active region and the second gate insulating film.

5. The semiconductor device of claim 4, wherein
the interface layer is a silicon dioxide film.

6. The semiconductor device of claim 1, wherein
each of the first transistor and the second transistor includes a gate electrode as a stack of a metal electrode and a polysilicon electrode.

7. The semiconductor device of claim 6, wherein
a side wall is provided on a side surface of the gate electrode.

8. The semiconductor device of claim 6, wherein
an upper portion of the polysilicon electrode is made of silicide.
